(19) United States
(12) Patent Application Publication
(10) Pub. No.: US 2012/0188711 A1
(43) Pub. Date: Jul. 26, 2012

(54) ELECTRONIC DEVICE

(75) Inventors: Biao ZENG, Wuhan City (CN); Xiang ZHANG, Wuhan City (CN); Qiu-Hua PENG, Wuhan City (CN); Cai-Hong ZOU, Wuhan City (CN)

(73) Assignees: HON HAI PRECISION INDUSTRY CO., LTD., New Taipei (TW); HONG FU JIN PRECISION INDUSTRY (Wuhan) CO., LTD., Wuhan City (CN)

(21) Appl. No.: 13/284,958

(22) Filed: Oct. 30, 2011

(30) Foreign Application Priority Data
Jan. 26, 2011 (CN) 201110028162.2

(51) Int. Cl. H05K 7/14

(52) U.S. Cl. 361/679.58

(57) ABSTRACT

An electronic device includes a computer, a backboard, a circuit board attached to the backboard, and a supporting base attached to the top surface of the circuit board. The computer case includes a bottom plate. The backboard is attached to the bottom plate. The backboard and the supporting base engage with the circuit board, and the backboard is located between the bottom plate and the circuit board, to prevent the circuit board from contacting the bottom plate.

### CROSS-REFERENCE TO RELATED APPLICATIONS

This application is related to co-pending application entitled, “ELECTRONIC DEVICE”, filed on ______, application Ser. No. ______, (Atty. Docket No. U.S.37953).

### BACKGROUND

1. Technical Field

The present disclosure relates to electronic devices, more particularly a heat dissipation device on a circuit board in an electronic device.

2. Description of Related Art

Electronic devices often include a chassis and a circuit board received in the chassis. The arrangement of the circuitry of the circuit board determines the efficiency of the circuit board. Usually, a plurality of electronic components, such as a CPU, is attached to the circuit board. When in assembly of the circuit board to the chassis, the heat sink is supported by a tray, the CPU is supported by a supporting bar, and a backboard is located between the circuit board and the chassis. A plurality of securing holes must be defined in the circuit board, to secure the tray, the supporting bar and the backboard to the circuit board. However, the plurality of securing holes influences the circuitry arrangement and may decrease the efficient operation of the circuit board.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an electronic device in accordance with an embodiment.

FIG. 2 is similar to FIG. 1, but showing a different aspect.

FIG. 3 is an assembled view of FIG. 1.

FIG. 4 is an assembled view of FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

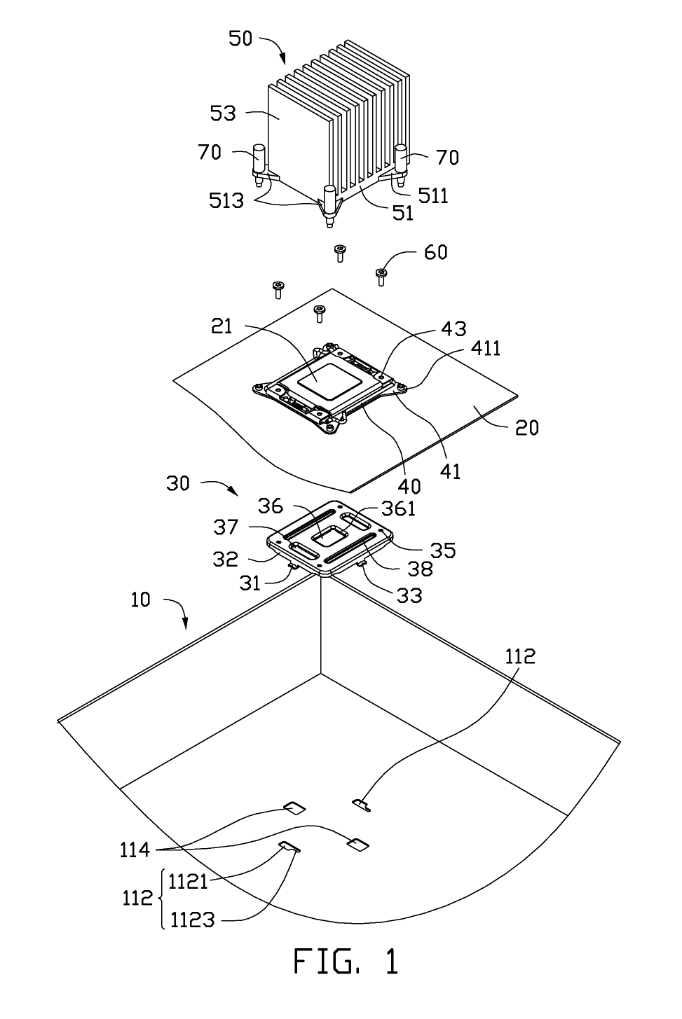

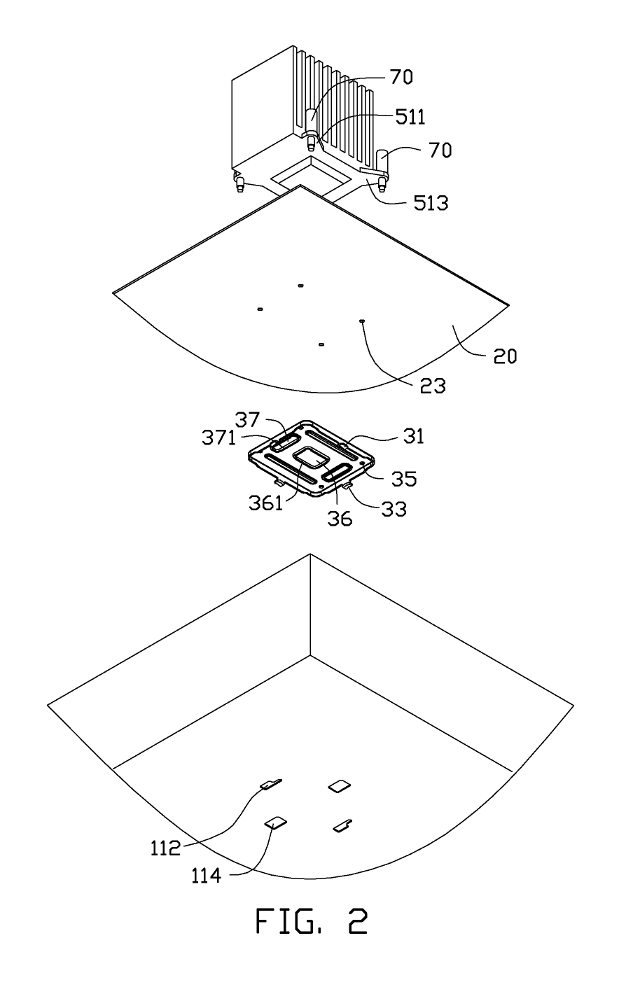

Referring to FIGS. 1 and 2, an electronic device in accordance with an embodiment includes a computer case 10, a circuit board 20, a backboard 30, a supporting base 40, and a heat sink 50.

The computer case 10 includes a bottom plate 11. Two opposite sliding slots 112 and two opposite securing holes 114 are defined in the bottom plate 11. Each sliding slot 112 includes a guiding portion 1121 and a limiting portion 1123. The size of the guiding portion 1121 is larger than that of the limiting portion 1123.

The circuit board 20 includes a CPU 21 and defines four through holes 23. In one embodiment, the four through holes 23 are arranged in a rectangle.

The backboard 30 may be a rectangle. Four flanges 32 extend from the four edges of the backboard 30. Two first clipping portions 31 extend from two of the four flanges 32, and two second clipping portions 31 extend from the other two of the four flanges 32. Four retaining holes 35 and an opening 36 are defined in the backboard 30. The four retaining holes 35 correspond to the four through holes 23. Four ribs 361 are located on the four edges of the opening 36. Two slots 37 and two strengthening portions 38 are defined in the backboard 30. Four ribs 371 extend from the four edges of each first slot 37. In one embodiment, the two slots 37 are located on opposite edges of the opening 36, and the two strengthening portions 38 are located on other opposite edge of the opening 36.

A positioning portion 41 is located on each corner of the supporting base 40. A positioning post 411 with a positioning hole 4112 is defined in the positioning portion 41. In one embodiment, each positioning portion 41 is triangular. Four fixing holes 43, corresponding to the through holes 23 and the retaining holes 35, are defined in the supporting base 40.

The heat sink 50 is attached to the CPU 21 and includes a rectangular base 51 and a plurality of fins 53 attached to the base 51. Two first securing portions 511 and two second securing portions 513 extend from the base 51. A fastener 70 engages with each first and second securing portions 511, 513. In one embodiment, the two first securing portions 511 are arranged on two opposite edges of the base 51, and the two second securing portions 513 are arranged at two corners of the base 51. In one embodiment, each first securing portion 511 and each second securing portion 513 are triangular.

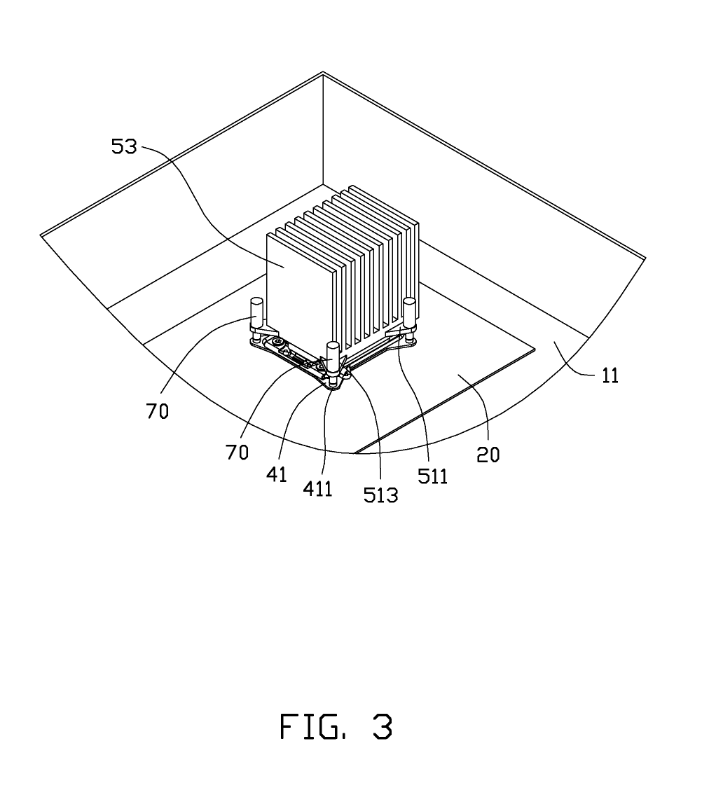

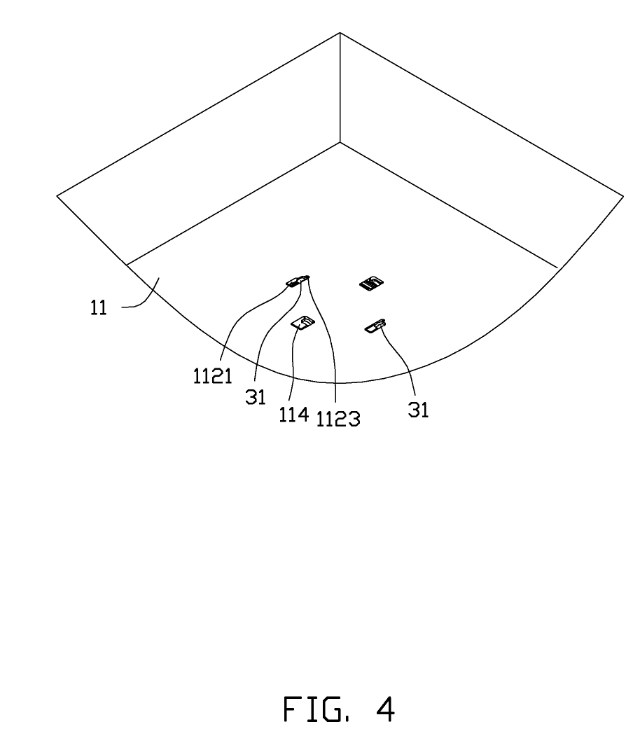

Referring to FIGS. 3-5, in assembly, the backboard 20 is attached to the bottom surface of the circuit board 20, and the supporting base 40 is attached to the top surface of the circuit board 20. The through holes 23 align with the retaining holes 35 and the fixing holes 43. Four fixing members 60 are engaged in the through holes 23, the retaining holes 35 and the fixing holes 43 in that order, to secure the backboard 30 and the supporting base 40 to the circuit board 20.

The heat sink 50 is attached to the top surface of the supporting base 40, and the first and second securing portions 511, 513 are attached to the positioning portions 411. The fasteners 70 are received in the positioning holes 4112, and the heat sink 50 is thus secured to the supporting base 40. In this way, the heat sink 50, the supporting base 40, the backboard 30 and the circuit board 20 are mounted together.

The heat sink 50, the supporting base 40, the backboard 30 and the circuit board 20 are received in the computer case 10, and the backboard 30 is attached to the bottom plate 11. The first clipping portions 31 are slid into the guiding portions 112, and the second clipping portions 33 are received in the securing holes 114. The backboard 30 is moved in a first direction substantially parallel to the bottom plate 11, until the first clipping portions 31 engage with the limiting portions 1123. In this way, the backboard 30 is secured to the bottom plate 11.

To disassemble, the backboard 30 is moved in a second direction opposite to the first direction, until the first clipping portions 31 are in the guiding portions 1121. The second clipping portions 33 can be lifted out of the securing holes 114, and the backboard 30 can be detached from the computer case 10. The fasteners 70 are disengaged from the positioning holes 4112, and the heat sink 50 can be removed from the circuit board 20. The fixing members 60 are removed from the through holes 23, the retaining holes 35 and the fixing holes 43, and the backboard 30 and the supporting base 40 can all be detached from the circuit board 20.

Although numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device comprising:
a computer case comprising a bottom plate;
a backboard attached to the bottom plate;
a circuit board attached to the backboard;
a supporting base attached to a top surface of the circuit board;
wherein the backboard is located between the bottom plate and the circuit board, to prevent the circuit board from contacting with the bottom plate.

2. The electronic device of claim 1, further comprising a fixing member, wherein the fixing member engages the backboard and the supporting base to the circuit board.

3. The electronic device of claim 1, wherein the bottom plate defines a sliding slot, and the backboard comprises a first clipping portion slidably received in the sliding slot.

4. The electronic device of claim 3, wherein the sliding slot comprising a guiding portion and a limiting portion communicating with the guiding portion, and a width of the guiding portion is larger than that of the limiting portion.

5. The electronic device of claim 1, wherein an opening is defined in the backboard, and a rib extends from the opening.

6. The electronic device of claim 1, further comprising a CPU located on the supporting base; a heat sink attached to the supporting base and contacting the CPU, wherein the supporting base comprises four positioning portions arranged to four corners of the supporting base, the heat sink comprises two first securing portions and two second securing portions, and the two first securing portions and the two second securing portions are engaged with the four positioning portions.

7. The electronic device of claim 6, wherein the heat sink comprises a rectangle base, the two first securing portions extend from opposite edges of the rectangle base, and each second securing portion is connected to two adjacent edges of the rectangle base.

8. The electronic device of claim 6, wherein each positioning portion is triangle, and each first securing portion and each second securing portion are triangle.

9. An electronic device comprising:
a computer case comprising a bottom plate, the bottom plate defining a sliding hole and a securing hole;
a backboard attached to the bottom plate and comprising a first clipping portion slidably received in the sliding slot and a second clipping portion slidably received in the securing hole;
a circuit board attached to the backboard;
a supporting base attached to a top surface of the circuit board;
wherein the backboard separates the circuit board from the bottom plate, the backboard is moveable in a direction substantially parallel to the bottom plate, to disengage the first clipping portion from the sliding slot, and to disengage the second clipping portion from the securing hole.

10. The electronic device of claim 9, further comprising a fixing member, wherein the fixing member engages the backboard and the supporting base to the circuit board.

11. The electronic device of claim 9, wherein the sliding slot comprising a guiding portion and a limiting portion communicating with the guiding portion, and a width of the guiding portion is larger than that of the limiting portion.

12. The electronic device of claim 9, wherein an opening is defined in the backboard, and a rib extends from the opening.

13. The electronic device of claim 12, wherein the backboard further comprises two slots and two strengthening portions, and the two slots are located on opposite sides of the opening, and the two strengthening portions are located on other opposite sides of the opening.

14. The electronic device of claim 9, further comprising a CPU located on the supporting base; a heat sink attached to the supporting base and contacting the CPU, wherein the supporting base comprises four positioning portions arranged to four corners of the supporting base, the heat sink comprises two first securing portions and two second securing portions, and the two first securing portions and the two second securing portions are engaged with the four positioning portions.

15. The electronic device of claim 14, wherein the heat sink comprises a rectangle base, the two first securing portions extend from opposite edges of the rectangle base, and each second securing portion is connected to two adjacent edges of the rectangle base.

16. The electronic device of claim 14, wherein each positioning portion is triangle, and each first securing portion and each second securing portion are triangle.
